(19) United States
(12) Patent Application Publication
(10) Pub. No.: US 2025/0101631 A1
(43) Pub. Date: Mar. 27, 2025

(54) MATERIAL COMPRISING A LAYER OF SELF-ASSEMBLED, ONE-DIMENSIONAL ZNO MICROCRYSTALS

(71) Applicants: Centre National de la Recherche Scientifique, Paris (FR); Universite de Montpellier, Montpellier (FR); Universitat Autonoma de Barcelona, Barcelona (ES)

(72) Inventors: Adrien CARRETERO, Clapiers (FR); David SANCHEZ FUENTES, Montpellier (FR); Lorenzo GARCIA, Montpellier (FR); Ricardo GARCIA, Clapiers (FR); Samir BOUISRI, Saint Bres (FR); Javier MORAL VICO, Barcelona (ES)

(21) Appl. No.: 18/291,058

(22) PCT Filed: Jul. 21, 2022
(86) PCT No.: PCT/FR2022/051467

§ 371 Date: Jan. 22, 2024

(30) Foreign Application Priority Data
Jul. 22, 2021 (FR) FR2107939

(51) Int. Cl. C30B 29/62; C30B 5/00; C30B 7/00; C30B 7/10; C30B 7/14; C30B 29/16; H03H 9/17; H03H 9/19

(52) U.S. Cl. CPC C30B 29/62; C30B 5/00; C30B 7/005; C30B 7/10; C30B 7/14; C30B 29/16; H03H 9/174; H03H 9/19

(57) ABSTRACT

The present invention relates to a multilayer material, comprising a solid substrate coated at least partially with a textured α-quartz buffer layer, the crystallographic direction of the α-quartz being parallel to the crystallographic direction of the silicon; and on said α-quartz buffer layer, a layer of one-dimensional epitaxial ZnO microcrystals (or epitaxial ZnO microwires), said microcrystals being self-assembled. The present invention also relates to a method for producing such a multilayer material, as well as to the industrial use thereof in various technical fields.

### ART

The present invention relates generally to the production of a self-assembled one-dimensional micro-crystal layer of (110) ZnO epitaxially grown on a solid support so as to form a material, and the different applications of such a material, particularly in the field of catalysis, in electronics and in photonics.

### PRIOR ART

Zinc oxide, which has the chemical formula ZnO, is one of the most studied semiconductor materials in the world due to the unique properties and large number of applications thereof. Zinc oxide is a transparent material with a refractive index of 2 in the massive form thereof. It is a large gap n-type semiconductor, the natural electrical conductivity of which is due to the presence of interstitial zinc atoms and oxygen vacancies. It has a direct wide band gap of 3.37 eV at room temperature. When doped with aluminium or magnesium, zinc oxide has a strong increase in the electrical conductivity thereof, while maintaining the transparency and chemical and thermal stability thereof [1]. Zinc oxide has thus been proposed as a suitable material for the manufacture of transparent and conductive electrodes in photovoltaic cells [2], and as a natural replacement for indium tin oxide (ITO) in liquid crystal displays and anodes of organic light emitting diode [3]. Moreover, ZnO has excellent photocatalytic and catalytic activity [4] especially in the form of mesocrystals [5-6] and has demonstrated a high sensitivity to the detection of gas in the form of nanowires [7].

Zinc oxide ZnO can crystallize mainly according to three structures, namely zinc blende, rocksalt and wurtzite. It is the wurtzite structure, belonging to the hexagonal reticular system, which is thermodynamically the most stable and hence the most common. In said form, the lattice parameters of ZnO are as follows: a=b=3.25 Å; c=5.20 Å; α=β=90° and γ=120°.

Zinc oxide ZnO in the wurtzite form thereof exhibits a spontaneous polarization along the [0001] direction of the hexagonal system due to the non-centro-symmetrical character of the zinc and oxygen tetrahedra forming same, which induces remarkable piezoelectric, thermoelectric, optical and catalytic properties. Such polar direction contains the most thermodynamically stable planes, therefore the preferential orientation of ZnO crystals, usually observed in thin films, corresponds to texture (0001). Such preferential orientation along the polar axis and the piezoelectric properties of ZnO make same a material of choice for the manufacture of energy harvesters, due to the piezoelectric properties thereof [8]. There is also a great interest in exposing the ZnO surfaces associated with the non-polar (or prismatic) planes thereof. Indeed, it is thereby possible to improve the catalytic performances of ZnO in synthesis reactions, such as the hydrogenation of CO₂ to form methanol [9], and photo-degradation of pollutants and dyes [4]. In addition, ZnO has other interesting properties such as a non-linear optical activity, luminescent in a plurality of wavelength ranges depending on the temperature at which same is annealed [10] and in particular for the optically stimulated luminescence (OSL) properties thereof [11].

Therefore, there is considerable interest in developing affordable synthesis methods for achieving a control of crystal orientation and anisotropic properties of thin films, powders and nanostructures of ZnO, which are very useful for the different applications thereof.

Different methods for the preparation of zinc oxide ZnO have already been proposed, such as chemical vapour deposition (CVD) [12], under vacuum and using gold as a catalyst. Among said methods, the only conventional method for preparing ZnO nanostructures is hydrothermal synthesis [13] involving the growth of one-dimensional ZnO nanocrystals on a polycrystalline seed layer, as described in the scientific publication “Effect of ZnO Seed Layer on the growth of ZnO Nanorods on Silicon Substrate” by Toea et al. [14]. Said method can be used only for the vertical and textured growth of ZnO nano- and microwires (the longitudinal axis of which is outside the plane of the substrate) along the polar axis on different technological substrates and not the direct heteroepitaxy thereof with a different orientation on silicon substrate [15-16].

The issues described hereinabove have motivated research aimed at the growth of non-polar planes in thin films and nanostructures of ZnO. Work has focused on the use of substrates with different symmetry and an interface constraint between substrates and ZnO [17-24].

However, none of the above-mentioned method can be used for easily and without the use of a catalyst or a seed layer or vacuum, achieving the self-assembly of planar ZnO one-dimensional microcrystals (longitudinal axis parallel to the plane of the substrate) epitaxially grown on silicon with a single, perfectly controlled orientation.

### DESCRIPTION OF THE INVENTION

In order to address the above-mentioned issues, the applicant has developed a multilayer material, comprising:
a solid support coated at least partially with a buffer layer of textured (100) α-quartz, the [100] crystallographic direction of α-quartz of which is parallel to the crystallographic direction [100] of silicon (100); and
on said buffer layer of (100) α-quartz, a layer of epitaxially grown one-dimensional micro-crystals of (110) ZnO (or epitaxially grown ZnO microwires), said micro-crystals being self-assembled.

Self-assembled microcrystals, as defined by the present invention, refer to microcrystals which are arranged in such a way that the longitudinal axes thereof are situated in a mean plane parallel to the plane of the quartz buffer layer, and which are oriented along two directions perpendicular to each other defined by the quartz layer.

According to a particular embodiment of the invention, the α-quartz buffer layer can include a controlled crystallization on which the growth of the ZnO microwires is carried out, in order to control the density and distribution thereof on the silicon substrate.

Advantageously, the thickness of the epitaxially grown one-dimensional micro-crystals of (110) ZnO can be comprised between 30 nm and 1.5 μm and can preferentially be on the order of 750 nm.

Advantageously, the length of the epitaxially grown one-dimensional micro-crystals of (110) ZnO can be comprised between 5 nm and 30 μm and can be preferentially on the order of 11 μm.

As a solid support, it is advantageously possible to use, for the material according to the invention, a solid support made of a material chosen from silicon, solid quartz, mica, corundum, germanium dioxide, magnesium oxide, strontium titanate SrTiO₃, LaAlO₃, lithium niobate, lithium tantalate, cerium oxide, gadolinium and cerium mixed oxides of CE₍₁₋ₓ₎GdxO₂ wherein x is such that 0<x<1, lanthanum aluminate, gallium nitride, yttrium-doped zirconium dioxide and gallium orthophosphate.

Preferentially, a solid support of mono-oriented crystalline silicon (100) will be used as solid support.

Advantageously, the microcrystals form a textured microstructure leading to a surface roughness comprised between 50 and 500 nm.

Advantageously, the one-dimensional micro-crystals of epitaxially grown (110) ZnO can cover at least 40% of the surface of the buffer layer of (100) α-quartz of said solid support. Said surface coverage rate can advantageously be greater than 40% of the surface of said buffer layer and can reach up to 90% of said surface.

Due to the intrinsic piezoelectric, photonic, fluorescent and catalytic properties of ZnO and the possibility provided by the manufacturing method according to the invention serves for synthesizing same in the form of planar microwires on a substrate, the multilayer material according to the invention can be used in industry in several technological fields.

Thereby, in the case where the multilayer material according to the invention includes a solid support of mono-oriented crystalline silicon (100), the subject matter of the present invention is the use of the multilayer material according to the invention in an electronic device chosen from MEMS, electro-mechanical materials, piezoelectric components, energy harvesters, photodetectors, mechanical wave specific filter oscillators, mechanical wave to electromagnetic wave transducers, acceleration and angular velocity sensors, mass sensors, or gas sensors

In the case where the solid support multilayer material according to the invention is not necessarily mono-oriented crystalline silicon (100), the further subject matter of the present invention is the use of the multilayer material according to the invention, for:
the manufacture of waveguides in the visible range (thereby taking advantage of the non-linear optical and fluorescence properties of ZnO), or
the manufacture of supported catalysts, in the presence or absence of noble metals or
as epitaxy template: the crystallinity of ZnO synthesized according to the method according to the invention enhancing the epitaxial growth of certain crystals while keeping the same original morphology.

In the case where the solid support multilayer material according to the invention is not necessarily mono-oriented crystalline silicon (100), a further subject matter of the present invention is the use of the multilayer material according to the invention for the manufacture of transparent and conductive electrodes and the manufacture of electronic devices using the transparent and conductive electrodes. More particularly, such electrodes can be used for the manufacture of different electronic devices wherein transparent microelectrodes of controlled size are needed, like e.g. in photovoltaic cells.

Nevertheless, for such an application, it is preferable that the solid support is made of mono-oriented crystalline silicon (100).

A further subject matter of the present invention is a micro electro-mechanical system in the form of a piezoelectric resonant membrane comprising a multilayer material according to the invention.

Finally, a further subject matter of the present invention is a method for manufacturing a multilayer material according to the invention, comprising the following steps:
A) a step of preparing a buffer layer of textured (100) α-quartz at least partially covering a solid support, so as to form a substrate for the epitaxial growth of ZnO micro-crystals (110);
B) a step of preparing a first composition comprising a solvent, and at least one ZnO precursor;
C) a step of preparing a second composition consisting of an aqueous solution of at least one heterocyclic organic compound having a diamond cage structure;
D) gradual feeding in, under stirring, of said second composition into said first composition, then maintenance under stirring for at least 10 minutes, in order to obtain a reaction mixture;
E) a step of preparing the surface of the buffer layer using said second composition prepared during step C) or said reaction mixture prepared during step D) by feeding in said substrate into a closed hydrothermal reactor, inside which the temperature is at least 60° C. and the pressure is at least 1 bar, for at least 15 minutes;
F) a step of washing said buffer layer with an acid solution;
G) a heat treatment step for the epitaxial growth of ZnO microcrystals by feeding in said substrate and said reaction mixture on said substrate into the closed hydrothermal reactor inside which the temperature is at least 60° C. and the pressure is at least 1 bar, for at least 15 minutes; then
H) a post-growth washing step with successively demineralized water and then ethanol, so as to dry the multilayer material thereby obtained.

Step A) consists in producing a buffer layer of textured (100) α-quartz covering at least partially a solid support, in order to form a substrate intended for the epitaxial growth of micro-crystals of (110) ZnO. Preferentially, such step can be carried out according to a method as taught by international application WO 2014/016506.

According to the invention, it is indispensable that the step of growing the ZnO microwires be carried out on a buffer layer in the form of α-quartz. Indeed, the presence of the surface of the monocrystalline α-quartz induces the nucleation and the growth of the one-dimensional micro-crystals of ZnO along a single crystallographic direction corresponding to an epitaxial relation. In other words, the quartz layer has the role of a nucleation surface on which the growth of ZnO is enhanced along an orientation for which the symmetry is similar and the distances between the rows of atoms are also similar. The result is a layer based on one-dimensional microcrystals based on mono-oriented ZnO, with a thickness, length, density and nanostructure that can be controlled.

During the step B of preparing the first composition, zinc salts chosen from nitrates, sulfates, carbonates, hydroxides, chlorides, acetates and oxides can be advantageously used as a ZnO precursor. A zinc nitrate will preferentially be used, and better still Zn(NO₃)₂·6H₂O present in a proportion of 0.1 M in said first composition.

Water, alcohol or a hydro-alcoholic mixture can typically be used as solvent.

During the step C of preparing the first composition, hexamethylenetetramine (HMTA) with the formula (CH₂)₆N₄ (preferentially present in a molar concentration of 0.1 M) can advantageously be used as heterocyclic organic compound contained in the second composition. Advantageously, one or a plurality of additives chosen from pH control agents (e.g. HCl), structuring or modifying agents or else porosity-promoting agents such as polymers, quaternary ammoniums and urea can be added to the second composition.

The second composition is then fed in gradually and under stirring (step D) into the first composition, and the mixture is then kept under stirring for at least 10 minutes in order to obtain a reaction mixture.

Such step D) is followed by a step E) of preparing the surface of the buffer layer using the second composition prepared during step C) or the reaction mixture prepared during step D) by feeding in said substrate into a closed hydrothermal reactor, inside which the temperature is at least 60° C. and the pressure is at least 1 bar, for at least 15 minutes. The reaction mixture prepared during step D) is preferentially used for such purpose. The heterocyclic organic compound (preferentially HMTA) contained in the second composition or the reaction mixture can then complex with the strontium used during step A) of preparing the buffer layer (cf. teaching International Application WO2014/016506).

Step E) of preparing a surface is followed by step F) of washing the buffer layer with an acid solution in order to remove any surface pollution.

Step F) can advantageously be carried out using an acid solution preferentially comprising one volume of hydrogen peroxide and four volumes of sulfuric acid, in order to remove the Zn residues. A hydrochloric acid solution can also be used for such purpose.

Step G) of heat treatment for the epitaxial growth of ZnO microcrystals is then carried out, by feeding in the substrate (formed during step A) by the solid support covered with the buffer layer of textured (100) α-quartz and the reaction mixture obtained during step D) on the substrate inside a closed hydrothermal reactor, inside which the temperature is at least 60° C. (advantageously between 60° C. and 200° C., and preferentially 95° C.) and the pressure is at least 1 bar, for at least 15 minutes. The duration of step G) can be chosen according to the length and width of the epitaxially grown ZnO microwires that it is desired to achieve, the width and length being all the more significant as the duration of the heat treatment step is longer. Thereby, as an example, when obtaining a length on the order of 11,000 nm and a width of 1,300 nm at 95° C. is desired, the duration of the heat treatment step should be on the order of 125 minutes (as illustrated in FIG. 3). Furthermore, the density of the ZnO microwires epitaxially grown on the buffer layer of the solid support also depends on the temperature used during the heat treatment step F) (as illustrated in FIG. 4), and also on the continuity of the α-quartz buffer layer during the completion of step A).

In practice, during step G), the substrate will be advantageously immersed in the reaction mixture, taking care not to exceed three quarters of the volume of the reactor. Advantageously, the substrate will be arranged, making sure that the buffer layer is placed on the bottom of the reactor so as not to deposit ZnO precursor powder (coming from the reaction mixture) on the surface of the substrate.

Finally, step G) of heat treatment for the epitaxial growth of ZnO microcrystals is followed by a step H) of post-growth washing, successively, with demineralized water, then ethanol, for optimal drying of the sample.

Steps G) and H) are repeated at least once, and preferentially at least twice, on the same substrate: e.g., a first cycle (comprising steps G) and H) will be used to remove the excess of catalyst (in particular containing strontium, as taught by international application WO 2014/016506) followed by an acid attack to completely clean the surface of the layer; then at least a second cycle will be carried out for the crystallization and formation of the ZnO microwires.

Such a method has the advantages of mild and sol-gel chemistry. More particularly, the method is simple, inexpensive and quick to implement. The method can be used for obtaining self-assembled one-dimensional micro-crystals of (110) ZnO epitaxially grown (or epitaxially grown ZnO microwires), with a high yield and a perfect control of orientation, of self-assembly, lengths, widths, density of epitaxially grown ZnO microwires, and nanostructure (presence of a controllable homogeneous porosity). The method according to the invention is also very flexible from a chemical point of view insofar as the mosaicity of the α-quartz buffer layer can be modified in order to control the degree of disorientation of the material obtained (as illustrated in FIGS. 1 and 2, which show the control of the orientation of the ZnO by means of the control of the mosaicity of the α-quartz buffer layer). Finally, an additional advantage of the method according to the invention is the use of wet process deposition, which makes the method compatible with micro- and nanofabrication techniques such as nanoprinting lithography.

A further subject matter of the present invention is a method for nanostructuring a multilayer material according to the invention, by controlled chemical etching using an acid solution.

Other advantages and features of the present invention will result from the following description, given as an example, but not limited to, and with reference to the enclosed figures and the examples.

### BRIEF DESCRIPTION OF THE FIGURES

The following examples illustrate the invention, with reference to the figures commented on hereinabove, without however limiting the scope of the figures:

FIG. 1 is a curve showing the change of the degree of disorientation of the material obtained from the degree of mosaicity of the α-quartz buffer layer (curve a), as well as the change of the mosaic structure and the crystalline quality of the quartz (100) layers and ZnO (110) microwires (curve b);

FIG. 2 shows the correlation of the mosaic structure and the crystal quality of the quartz layers (100) and ZnO microwires (110) from x-ray diffraction data;

FIG. 3 comprises two experimental curves representing the change as a function of time, of the length (left-hand curve) and the width (right-hand curve), respectively, of epitaxially grown ZnO microwires synthesized on a α-quartz buffer layer, according to the method according to the invention;

FIG. 4 comprises an experimental curve showing the change as a function of temperature, of the density of epitaxial ZnO microwires synthesized on a α-quartz buffer layer according to the method according to the invention, as well as the 5 SEM images of the epitaxial ZnO microwires used for the plotting the curve;

FIG. 5 relates to the structural study of the quartz layer and shows two 2D and 1 D XRD diffraction diagrams (b) (intensity in arbitrary units as a function of the angle 2θ in degrees). The additional figure inserted in part b) shows the analysis of the degree of mosaicity of the ZnO microwire layer which has a degree of mosaicity of 1.3°. FIG. 5c is a pole figure: quartz (100) 2θ=20.8° and 3-dimensional representation of the orientation and relationship of the two crystallographic domains of the epitaxial quartz layer on silicon;

FIG. 6 relates to the microstructural study of the quartz layer from optical microscopy images (a), SEM (b and d) and AFM (c);

FIG. 7 relates to the structural study of the ZnO microwire layer:
a) two-dimensional XRD diffraction diagram (intensity in arbitrary units as a function of angle 2θ in degrees);
b) analysis of the degree of mosaicity of the ZnO microwire layer which shows a degree of mosaicity of 2.5°;
c) SEM image showing the microstructure and the two crystallographic domains of the ZnO microwires;
d) pole figure: ZnO (110) 2θ=56.7° and three-dimensional representation of the orientation and relation of the two crystallographic domains of the ZnO microwire layer on the α-quartz layer epitaxially grown on silicon;
e) MET image of the two ZnO microwires (crystallographic domains 1 and 2) on a quartz layer on a silicon substrate;
f) high resolution MET image of the cross-section of a ZnO microwire on a quartz layer on a silicon substrate oriented along the crystallographic direction [1-10];
f) crystallographic model that represents the HRTEM image with an epitaxy relation [110] ZnO(110) // [100]*α-Quartz(100) between the ZnO microwires and the α-quartz layer;

FIG. 8 relates to the microstructural study of the ZnO microwire layer and comprises the analysis of crystal size characterized by optical images (a), using SEM (b and c) and AFM (d and e);

FIG. 9a shows the chemical analysis by EDS highlighting the composition of zinc and oxygen elements of ZnO microwires; FIG. 9b shows the ability to guide the light of the ZnO microcrystals using an optical microscope; FIG. 9c shows the fluorescent activity of ZnO microwires;

FIG. 10 is an explanatory diagram known to a person skilled in the art illustrating the cycle of the catalytic conversion of CO₂ to methanol when hydrogen is obtained from sources without CO₂;

FIG. 11 is a calibration curve for CO during the catalytic conversion of CO₂ to methanol (example 2);

FIG. 12 is a calibration curve for CO₂ during the catalytic conversion of CO₂ to methanol (example 2);

FIG. 13 is a curve of methanol during the catalytic conversion of CO₂ to methanol (example 2);

FIG. 14 shows a comparison of the change of the STY of the material according to example 1 used as catalyst during the catalytic conversion of CO₂ into methanol, and of the commercial catalyst (CatCom) under different conditions (example 2);

FIG. 15 shows the correlation between the conversion and the selectivity of methanol (example 2);

FIG. 16 relates to the structural study of the ZnO microwire layer (a and b) and comprises 2D and 1D, respectively, XRD diffraction diagrams (intensity in arbitrary units as a function of the angle 2θ in degrees) (Inset image), and the analysis of the degree of mosaicity along the crystallographic direction [110] of the ZnO microwire layer obtained;

FIG. 17 relates to the microstructural study of the ZnO microwire layer; the analysis of the crystal size is characterized by optical images (a), SEM (b and c) and AFM (d and e);

FIG. 18 (corresponding to example 4) shows the use of the catalyst obtained in example 4 as a low frequency energy harvester (61 Hz);

FIG. 19 (corresponding to example 5) shows a micro electro-mechanical system (MEMS) based on ZnO microcrystals epitaxially grown in the form of a piezoelectric resonant membrane for surface areas of 1 mm², 4 mm², 9 mm² and 16 mm², the etchings made making it possible to obtain membranes 1 μm thick allowing light to be diffused (red squares: 10a and 10b), as well as a vibration spectrum of a (MEMS) containing ZnO microcrystals epitaxially grown as a piezoelectric resonant membrane with a surface area of 9 mm² (10c);

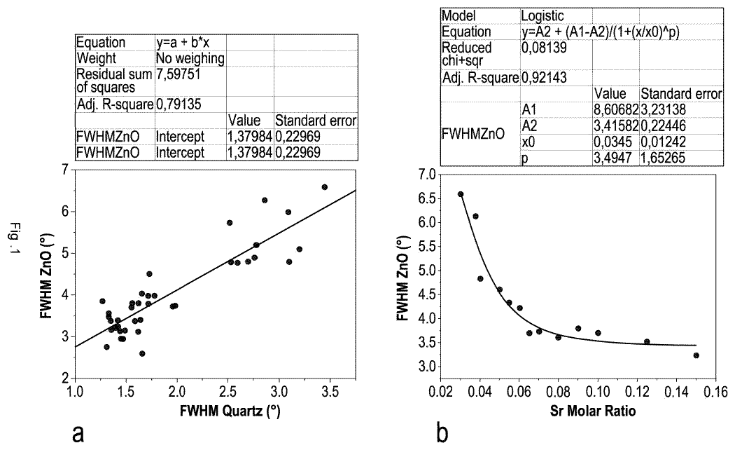

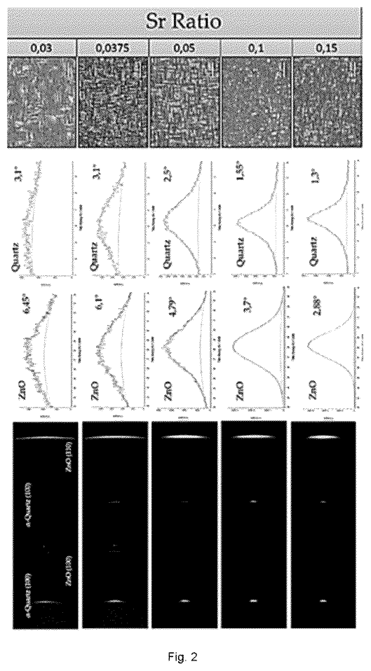

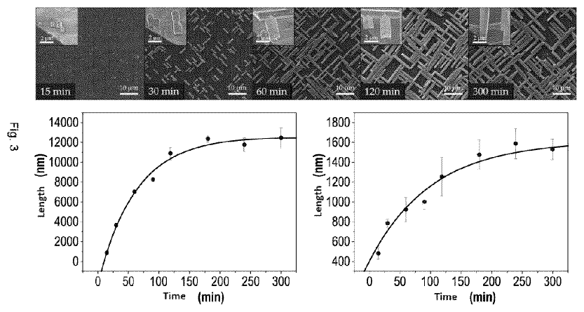

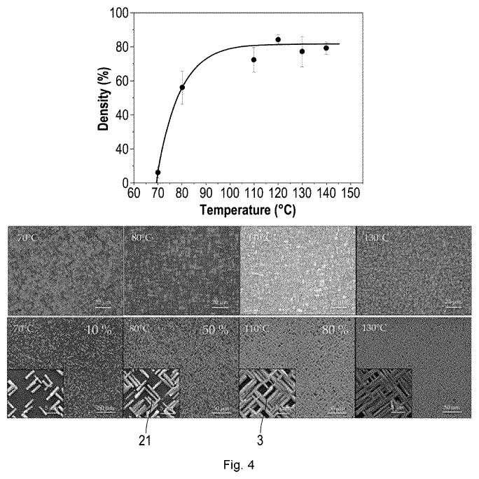

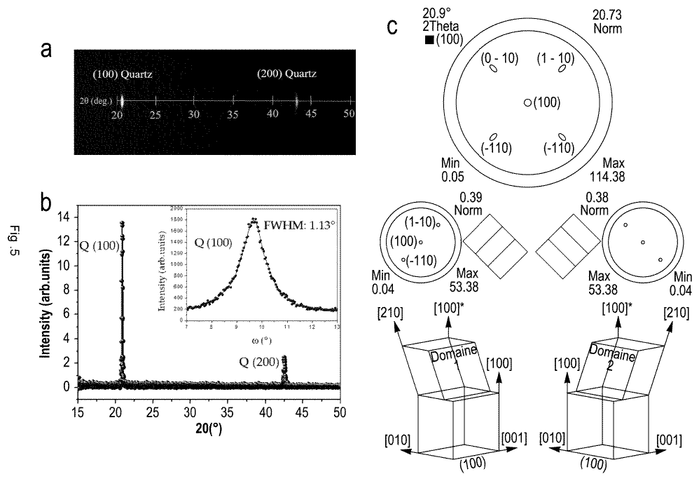

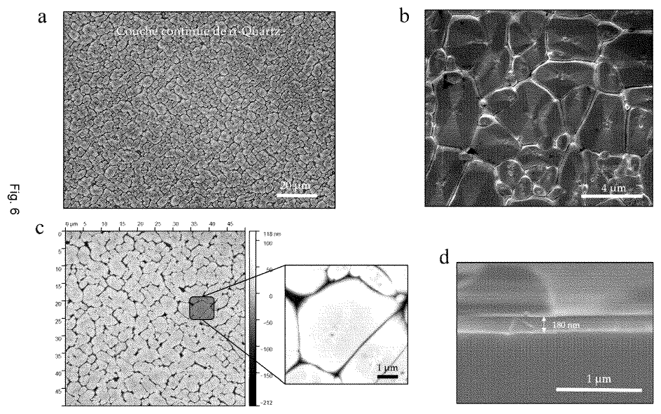

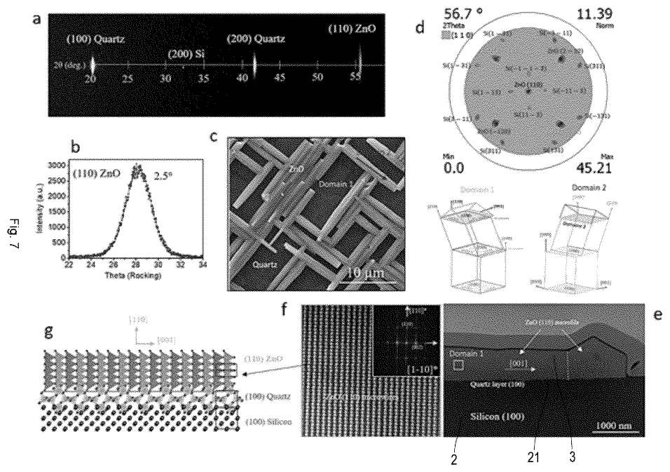

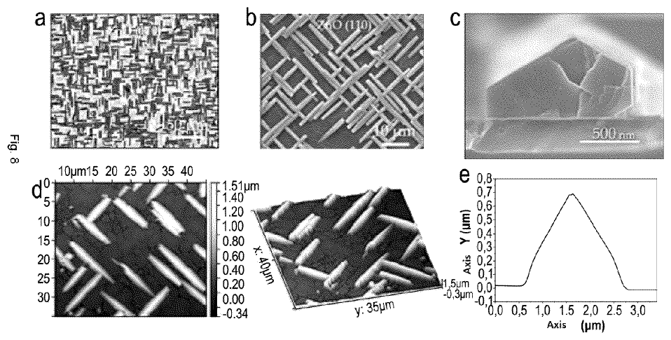

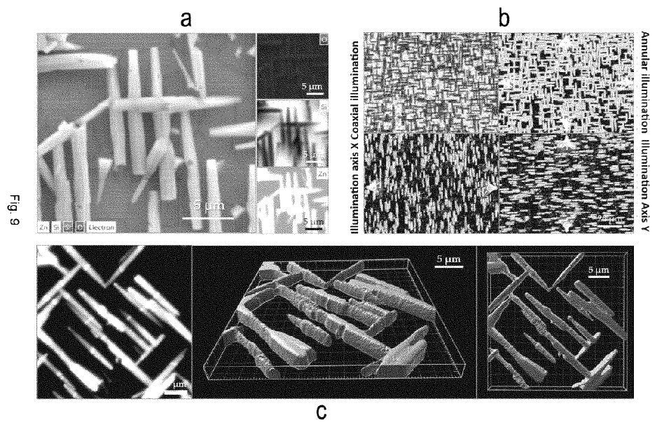

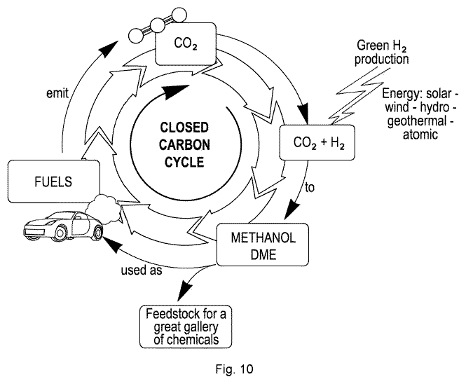

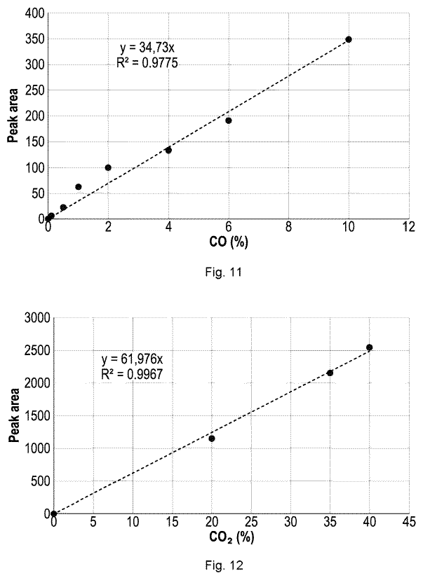

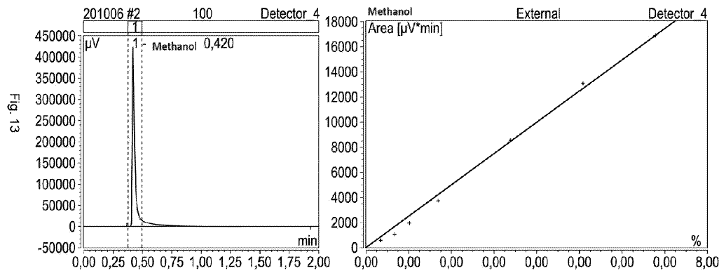

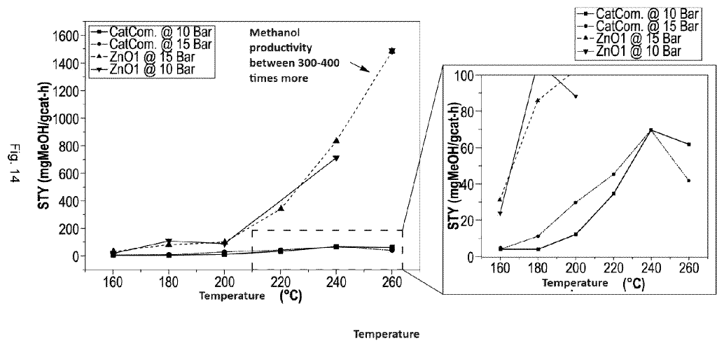

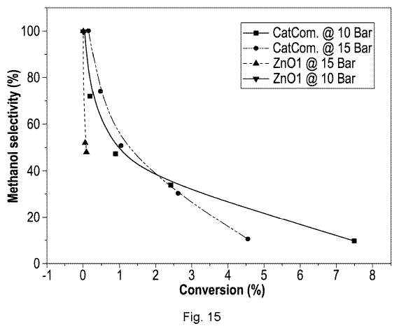

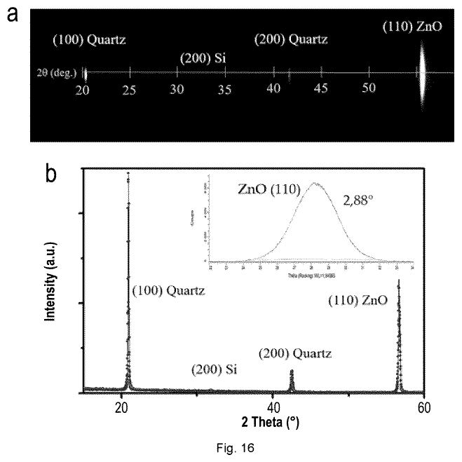

FIG. 20 comprises a graph showing the increase in the STY value with the degree of chemical attack and low magnification SEM images of ZnO samples on quartz with different degrees of attack with HCl concentrations: 0.37 0.75 1.48 2.94 (20a), a MET image (20b) and a SEM image (20c) with greater magnification of the cross section of a ZnO microwire along the crystallographic direction (001) after etching for 5 minutes under ultrasound with a dilute HCl solution of 2.94 mM. FIGS. 1 to 4 have been described in the preceding descriptive part, whereas FIGS. 5 to 20 are described in greater detail along the following examples, which illustrate the invention without limiting the scope thereof.

### EXAMPLES

The nature of the products used for the manufacture of ZnO microcrystals, the reactor and the method used, as well as the characterization methods are discussed in detail hereinafter.

### Products, Raw Materials:

98% tetraethoxyorthosilane (TEOS), sold by Sigma-Aldrich,
ethanol (EtOH),
ultra-pure H₂O.
hydrochloric acid (HCl), sold by Sigma-Aldrich,
strontium chloride (SrCl₂·6H₂O), sold by Sigma-Aldrich,
zinc nitrate (Zn(NO₃)₂ 6H₂O), sold by Sigma-Aldrich,
hexamethylenetetramine (HMTA) (CH₂)₆N₄, sold by Sigma-Aldrich,
Polyethylene glycol hexadecyl ether sold under the trade name Brij-58® by Sigma-Aldrich,
sulfuric acid (H₂SO₄), sold by Sigma-Aldrich,
hydrogen peroxide (H₂O₂), sold by Sigma-Aldrich.

### Instruments and Tests for Structural and Microstructural Characterization

A complete physical and chemical characterization was performed using complementary techniques at different scales, in order to characterize the fluorinated layer formed, using:
a digital optical microscope marketed by KEYENCE under the trade name VHX7000;
a Scanning Electron Microscope-Field Emission (SEM-FEG) marketed by Hitachi under the trade name SU6600;
an atomic force microscope (AFM) marketed by Veeco under the trade name MULTIMODE;
a diffractometer marketed under the trade name GADDS D8 in a Bruker assembly, copper irradiation 1.54056 Å;
a high resolution transmission electron microscopy (hereinafter referred to as METHR) marketed by FEI under the trade name TITAN;
chemical analysis by EDS (energy dispersive X-ray spectroscopy);
a confocal microscope Zeiss LSM880 with a 63×/1.4 lens
a 405 nm diode laser
an Airyscan detector (GaAsP 32-channel photomultiplier Tube Array Detector (PMT);
an ImageJ software.
a 3/4D display and analysis software marketed by Oxford Instruments under the trade name Imaris;
a gas chromatograph Agilent 7890B equipped with a 25 meter CarboPlot P7 column and a TDC detector;
a gas chromatograph coupled to a flame ionization detector (GC-FID);

### Example 1: Manufacture of a First Example of a Multilayer Material According to the Invention

### Preparation and Characterization of the α-Quartz Buffer Layer (Step A)

The preparation is carried out on the basis of the teaching of the International Application WO 2014/016506, as indicated below.

A precursor solution having the following initial composition (in moles) is prepared: 1TEOS, 0.3 Brij-58, 25EtOH, 0.7HCl, 0.05 SrCl₂·6H₂O.

The precursor solution of the buffer layer 21 was deposited on a silicon Si(100) substrate 2 having a thickness of 100 μm and a surface area of 2 cm×6 cm. The silicon substrate 2 used included a 2.2 nm thick native SiO₂ layer. The precursor solution was deposited on the substrate by centrifugal coating at room temperature, at a speed of 1500 rpm, for 30 s.

After depositing the precursor solution, the silicon substrate 2 was subjected to a heat treatment in order to consolidate the silica layer in a tubular furnace, under air and at atmospheric pressure: direct dipping at 450° C., then maintaining at 450° C. for 5 minutes. At the end of the treatment, a silicon support (100) was obtained covered with a layer of amorphous silica precursor of α-quartz.

Then, the silicon substrate thereby obtained was subjected to a second heat treatment in a tubular furnace, under air and at 12 L/minute: direct dipping at 980° C., then maintaining at 980° C. for 5 hours.

The furnace was then switched off and the substrate was allowed to cool down to 25° C. at a rate of 3° C./minute.

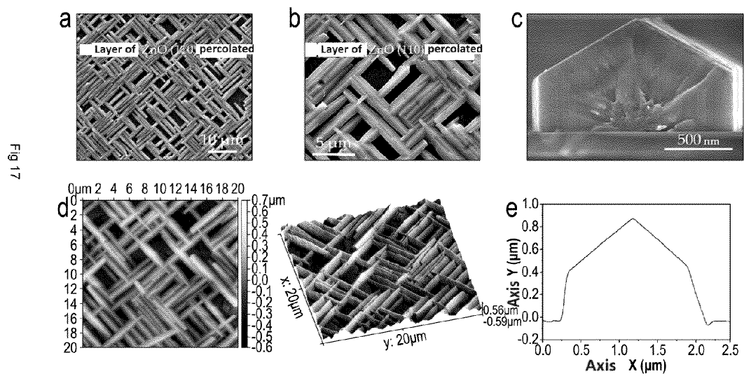

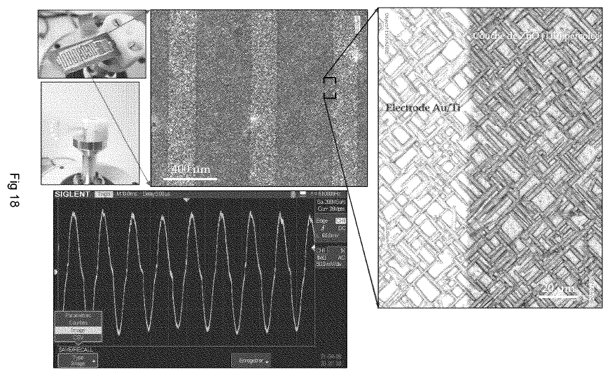

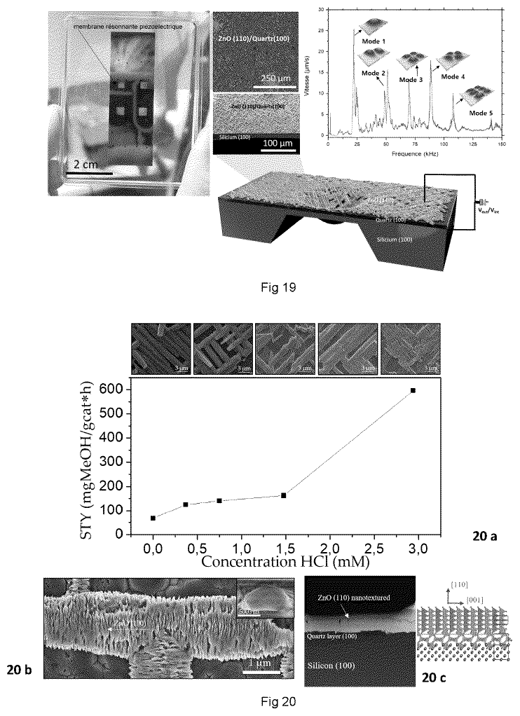

At the end of the cooling, a silicon support (100) was obtained, covered with a layer of α-quartz 21 which was then characterized. The results of the structural and microstructural study of the α-quartz layer obtained are given in FIGS. 5 and 6, respectively.

FIGS. 5a and 5b show the XRD diffraction diagrams (intensity in arbitrary units as a function of angle 2θ in degrees) and the degree of mosaicity of the quartz layer obtained. The XRD analysis shows that quartz is textured (100), with the crystallographic direction [100] of α-quartz parallel to the crystallographic direction [100] of silicon (100). FIG. 5c is a pole figure: α-quartz(100) 2θ=20.9°, associated with the reflection of the plane (100) of the α-quartz, which confirms that the latter is indeed epitaxially grown and also shows the presence of two quartz domains oriented at 90° from each other. The bottom figure of FIG. 5c shows a model of 3-dimensional representation of the orientation and relation of two crystal domains of the dense layer of α-quartz epitaxially grown on silicon.

The optical images of FIG. 6 show the continuity of the α-quartz layer 21 obtained with a roughness (RMS=30 nm) determined using an atomic force microscope (usually known by the acronym AFM) sold by Veeco (FIGS. 6 a, b and c). The thickness of the layer was characterized by scanning electron microscopy-field emission (SEM-FEG) images with a Hitachi SU6600 SEB, showing a thickness of 180 nm (FIG. 6d).

### Preparation and Characterization of the ZnO Microwire Layer (Steps B) to F)).

The growth of the ZnO microwires 3 on the α-quartz buffer layer 21 was carried out by hydrothermal synthesis at low temperature and pressure. Such conditions make it possible to use different types of glass (Pyrex) or Teflon reactors which makes the invention affordable, inexpensive and feasible on a large scale.

At first, an aqueous solution of zinc nitrate hexahydrate Zn(NO₃)₂·6H₂O with a molar concentration C_{Zn}=0.1 M (step B) was prepared.

In parallel, an aqueous solution of hexamethylenetetramine (HMTA) ((CH₂)₆N₄ with a molar concentration C_{HMTA}=0.1 M (step C) was prepared.

The HMTA solution was then added by dripping with a pipette into the zinc nitrate solution under stirring at 450 rpm⁻¹. The mixture was then stirred for 10 minutes (step D). The buffer layer was then washed (step E).

The epitaxial growth of the ZnO microwires 3 was carried out (step F) on the surface of the quartz epitaxy layer (100) on silicon substrate (Si(100) (dimensions: 100 μm in thickness and surface area of 2 cm×6 cm) by hydrothermal synthesis at 95° C., and at a pressure of approximately 210 kPa (2.1 bar) for 300 minutes. Such step was performed at least twice:
the first cycle served to remove the excess Sr catalyst located at the surface, used during the crystallization of the α-quartz buffer layer; then,
the sample was cleaned with a mixture of sulfuric acid and hydrogen peroxide in a proportion of 4:1, respectively, to clean the ZnO residues resulting from the first cycle; finally,
a second cycle was needed for the actual crystallization and formation of the ZnO microwires.

The new epitaxy between ZnO and the buffer layer 21 of α-quartz was determined by X-ray diffraction using the diffractometer.

FIGS. 7a and 7b show the XRD diffraction diagram (intensity in arbitrary units as a function of the angle 2θ in degrees) and the aforementioned degree of mosaicity of the obtained layer 3 containing ZnO microwires. The XRD analysis shows that ZnO is textured (110) with the crystallographic direction [110] of α-quartz parallel to the crystallographic direction [100] of quartz (100) and of the silicon substrate (100). FIG. 7b shows a degree of mosaicity of 2.5°. The SEM image shown in FIG. 7c shows the microstructure and two possible crystallographic domains of the microwires 3 of ZnO. FIG. 7d shows a pole figure: ZnO (110) 2θ=56.7°. The pole figure of taken at 2θ=56.7°, associated with the reflection of the (110) plane of ZnO, confirms that the latter is indeed epitaxially grown and shows, moreover, the presence of two ZnO domains oriented at 90° from each other in the same way as the domains of quartz. The lower part of FIG. 7D shows a model of the representation of the two crystallographic domains in three dimensions with the orientation and the epitaxial relation between the layer 3 of the ZnO microwires and the dense layer 21 of α-quartz. The microwires of ZnO grow according to the relation [110] ZnO(110) // [100]*α-Quartz(100) // [100]*Si(100) and are positioned on the two domains of the quartz. Such results show the heteroepitaxy of ZnO(110) microwires on silicon 2 for the first time, at a temperature below 100° C. due to the use of inexpensive chemical solution deposition methods that can be carried out on a large scale. FIG. 7e shows a low magnification MET image in the bright-field mode cross-section of the two ZnO microwires (crystallographic domains 1 and 2) on a quartz layer on a silicon substrate oriented along the crystallographic direction (100). FIG. 7f shows a high-resolution image of the cross-section in the bright-field mode of a ZnO microwire on a quartz layer on a silicon substrate oriented along the crystallographic direction [1-10]. The METHR analysis confirms the results obtained by XRD and in particular the texture of the ZnO (110) microwires 3 as well as the epitaxy relation [110] ZnO(110) // [100]*α-Quartz(100) between the ZnO microwires and the α-quartz layer (see the crystallographic model shown in image 7g).

The microstructural analysis and the measurements of the dimensions of the microwires were carried out by optical microscopy and field emission scanning electron microscopy. The microstructural analysis shows that the multilayer material according to the invention obtained at the end of the two cycles comprises a support composed of a layer of quartz (100) on silicon (100) covered with a layer containing ZnO microwires (110), as illustrated in FIG. 9.

FIG. 8 shows the results of the topographic and microstructural study of the ZnO microwire layer 3 thereby obtained using optical microscopy (FIG. 8a) and SEM (FIGS. 8b and 8c). The continuity of the layer as well as the size of the crystals is characterized by SEB and AFM images (FIG. 8D). The layer obtained is 70% coated with ZnO crystals with a length of 11,000 nm, a width of 1,400 nm and a height of 750 nm. The distribution of the microwires is perfectly homogeneous throughout the surface of the sample.

The fine characterization of the ZnO microwires is illustrated more particularly in FIG. 9:
FIG. 9a shows the EDS chemical analysis revealing the composition of zinc and oxygen elements of ZnO microwires;
FIG. 9b shows the ability to guide the light of the ZnO microcrystals using an optical microscope;
FIG. 9c shows the extraordinary fluorescent activity of ZnO microwires.

The images of FIG. 9 were acquired on a Zeiss LSM880 confocal microscope with a 63×/1.4 lens. The excitation source used was a 405 nm diode laser and the wavelength emission was adjusted to 552 nm with a 495-550 nm bandpass filter, which provides a maximum photon collection. Multidimensional scans were acquired via an Airyscan detector (GaAsP 32-channel tube array detector (PMT) photomultiplier). The 3D images were acquired by performing z images every 0.18 μm. 2D images were generated by performing a z-projection of the z-stack with the ImageJ software. The 3D rendering of the z-stacks was generated with the display and analysis software 3/4D Imaris (Oxford Instruments).

### Example 2: Application to Catalysis of the First Example of Multilayer Material 1 According to the Invention, as Obtained in Example 1

Methanol is a potential liquid energy or a hydrogen carrier as well as an important raw material for producing basic chemicals and key chemical intermediates. Catalytic conversion of CO₂ to methanol was considered a highly desirable method in a sustainable methanol-based economy, as same is also an important approach to reducing greenhouse gases when hydrogen is obtained from CO₂-free sources (cf. FIG. 10)

Supported copper materials (e.g. Cu—ZnO, Cu—ZrO₂ and Cu—ZnO—ZrO₂) have proven to be promising catalysts for such transformation, due to the high performance thereof [25].

Such example aims to show the catalytic properties during a conversion process of CO₂ into methanol, of a layer 3 containing (110) ZnO nanowires epitaxially grown on a buffer layer 21 containing (100) quartz on a substrate 2 of (100) silicon, such as the layer obtained in example 1.

It is shown hereinafter that the yield of the new catalyst 1 for the conversion of CO₂ into methanol is between 30 and 50 times higher than the best commercial catalyst existing to date, with a selectivity of 100%.

The catalyst according to the invention (multilayer material obtained in example 1) based on (110)ZnO/(100)Quartz/(100)Si was tested using 107 μg of ZnO on a quartz layer on a silicon substrate.

### Methodology

The catalyst according to the invention (multilayer material 1 obtained in example 1) was placed in a fixed bed reactor or plug flow reactor. H₂ and CO₂ were sent to the reactor. The catalytic reaction produced methanol and sometimes carbon monoxide CO (depending on the selectivity of the catalyst). The analysis of the gases was carried out at the outlet, entrained by a flow of N₂.

The temperature was first increased to 160° C. at a rate of 5° C./minute and, at the same time, the reactor was fed with a mixture of CO₂ and H₂ at a theoretical ratio of 1:3 at a pressure of 5 bar at 10 ml/minutes. Once the desired conditions were reached, we waited 30 minutes to stabilize the system, then a sample was taken using a sampling bag in order to decrease the gas pressure after the reaction. The catalytic properties of the sample (110)ZnO/(100)Quartz/(100)Si were then compared with a high performance commercial catalyst having the following composition: 10.1% Al₂O₃, 63.5% CuO, 24.7% ZnO and 1.3% MgO (by ALPHA AESAR).

The same procedure was followed with a commercial catalyst, wherein 0.025 mg of catalyst were deposited in powder form in the reactor.

Table 1 below shows the catalytic conditions tested:

TABLE 1
Set of conditions used in the catalytic tests

| Pressure | Temperature | Flow rate |
|---|---|---|
| (bar) | (° C.) | (ml/min) |
| 10 | 160 | 10 |
| 10 | 180 | 10 |
| 10 | 200 | 10 |
| 10 | 220 | 10 |
| 10 | 240 | 10 |
| 10 | 260 | 10 |
| 15 | 160 | 10 |
| 15 | 180 | 10 |
| 15 | 200 | 10 |
| 15 | 220 | 10 |
| 15 | 240 | 10 |
| 15 | 260 | 10 |

Each time the conditions of the system were changed, we waited for 20 minutes to stabilize the reaction. A gas chromatograph series Agilent 7890B equipped with a 25 meter CarboPlot P7 column and a TDC detector was used to analyse the CO₂ and CO content after the reaction.

The CO calibration (cf. FIG. 11) was carried out using pure CO at concentrations greater than 1% by volume and a mixture of 1% CO in N₂ at concentrations less than 1%, obtaining a detection limit of 0.1% by volume.

The methanol concentration of the gas leaving the reactor was also analysed using FID chromatography, for calculating the methanol concentration in the gas obtained. Such result is then used for calculating the spatio-temporal yield (STY), which gives an idea of the amount of methanol obtained per gram of catalyst used in the catalytic test. Methanol calibration (see FIG. 13) was carried out using the technique called “Mariotte's bottle”, where methanol was placed in a flask and different quantities of the bottle head containing evaporated methanol were analysed using FID gas chromatography.

The conversion and selectivity of the catalysts tested were calculated using the following formulae:

$$Conversion ( \% ) = \frac{{X}_{{CO}_{2} o} - {X}_{COi} - {X}_{MeOHi}}{{X}_{{CO}_{2} o}} \cdot 100$$

$$Methanol selectivity ( \% ) = \frac{{X}_{MeOHi}}{{X}_{COi} + {X}_{MeOHi}} \cdot 100$$

$$CO selectivity ( \% ) = \frac{{X}_{COi}}{{X}_{COi} + {X}_{MeOHi}} \cdot 100$$

With X_{CO20} denoting the initial CO₂ concentration (no catalytic reaction, X_{CO}i denoting the CO concentration at each set of conditions, and X_{MeOH}i denoting the methanol concentration at each set of conditions.

The space-time yield STY was calculated using the following formula:

$$S T Y = \frac{{X}_{MeOHi} \cdot {M}_{MeOH} \cdot GHSV}{\frac{1 \cdot 8.3144 \cdot T}{Pa}}$$

Where M_{MeOH} is the molecular weight of methanol (32.04 g/mol), T is temperature, Pa is the atmospheric pressure, and GHSV is the hourly space velocity, expressed in

$$\frac{L}{{g}_{cat} \cdot h} .$$

### Results

The catalytic comparative results are shown in FIG. 14 after the preparation of the quartz buffer layer 21 and the preparation of the ZnO microwires 3.

FIG. 14 shows that the ZnO nanowire catalyst has a remarkably higher STY compared to the commercial catalyst. As expected, in the case of the commercial catalyst, the STY increases between 160° C. and 240° C. but, after the latter value, the STY decreases. In addition, the increase in pressure increases the production of methanol at low temperature.

In the case of a layer 3 of epitaxially grown nanowires of ZnO (catalyst denoted by ZnO-1), it is observed that the STY increases exponentially from 220° C. on. At lower temperatures, pressure does not seem to be a crucial factor, as STY values are very similar for 10 bar and 15 bar. For temperatures above 200° C., the pressure becomes higher.

In comparison, the sample of ZnO nanowires epitaxially grown on quartz produces about 30 to 50 times more methanol per gram of catalyst than the commercial catalyst (with noble metals) depending on the conditions used.

A heat treatment at 900° C. for 5 hours applied to a catalyst according to the invention makes it possible to improve the catalytic properties thereof during a process of catalytic conversion of CO₂ into methanol.

### Selectivity

It was observed that by increasing the temperature, the conversion is increased but, by using the commercial catalyst after 260° C., the STY is decreased. Such phenomenon can be explained by selectivity. As observed in FIG. 15, when the conversion is increased, the selectivity of the methanol of the reaction is considerably reduced.

In the case of the so-called ZnO-1 catalyst based on ZnO microcrystals, no CO signal is observed at temperatures below 240° C. At 10 bar, no CO signal is observed nor at 240° C. At 15 bar, a small amount of CO is observed, reducing the selectivity of methanol to about 52% at 240° C., and to 48% at 260° C. Yet it is the first noble metal-free catalyst with a selectivity of 100% and a productivity of 50 times more methanol than any other catalyst.

### Example 3: Manufacture of a Second Example of Multilayer Material 1 According to the Invention

The present example shows the preparation of a layer 3 containing ZnO microwires, long and dense enough to be completely percolated. The planar conformation of ZnO microwires can then be used for the manufacturing of a low frequency energy harvester prototyping using a vibration system and interdigitated electrodes. The extra-thin silicon substrate 2 is totally flexible, which allows the device to operate correctly. Such device works as well as an axial photodetector.

### Preparation and Characterization of the Buffer Layer 21 of α-Quartz (Step A)

A precursor solution having the following initial composition (in moles) was prepared: 1TEOS, 0.3Brij-58, 25EtOH, 0.7HCl, 0.05 SrCl₂·6H₂O.

The precursor solution of the buffer layer was deposited on a silicon substrate (Si(100)) (dimensions: 100 μm in thickness and surface area of 2 cm×6 cm) with a 2.2 nm thick native SiO₂ layer using spin coating at room temperature, at a speed of 1,500 rpm for 30 s.

After depositing the precursor solution, the silicon substrate was subjected to heat treatment for the consolidation of the following silica layer in a tubular furnace, under air and at atmospheric pressure: direct dipping at a temperature of 450° C., then maintaining at 450° C. for 5 minutes.

After consolidation of the amorphous silica layer precursor of α-quartz, the silicon substrate was subjected to the following heat treatment in a tubular furnace, under air and at 12 l/minute: direct dipping at a temperature of 980° C., then maintaining at 980° C. for 5 hours.

The furnace was then switched off and the substrate was allowed to cool down to 25° C. at a rate of 3° C./minute.

At the end of the cooling, the silicon support (100) was obtained covered with a layer of α-quartz which was then characterized (FIGS. 5 and 6).

### Preparation and Characterization of the ZnO Microwire Layer (Steps B) to F))

The growth of ZnO microwires on the α-quartz buffer layer was carried out by hydrothermal synthesis at low temperature and low pressure. These conditions make it possible to use different types of reactors based on glass (Pyrex) or Teflon which makes the invention affordable, low cost and feasible on a large scale.

Firstly, an aqueous solution of zinc nitrate hexahydrate Zn(NO₃)₂·6H₂O was prepared, including the molar concentration C_{Zn}=0.1 M (step B)).

Separately, an aqueous solution of hexamethylenetetramine ((HMTA) (CH₂)₆N₄ was prepared, including the molar concentration C_{HMTA}=0.1 M (step C)).

The HMTA solution was then added by dripping with a pipette onto the zinc nitrate solution under stirring at 450 rpm. The mixture was then stirred for 10 minutes (step D). The buffer layer was then washed (step E).

The epitaxial growth of ZnO microwires (step F) was carried out on the surface of the epitaxy layer of quartz (100) on silicon substrate (Si(100)) (dimensions: 100 μm in thickness and surface area 2 cm×6 cm) by hydrothermal synthesis at a temperature of 110° C. and a pressure of approximately 210 kPa (2.1 bar) for 300 minutes. It is advantageous that the step is carried out at least twice. A first cycle will serve to remove the excess SR catalyst located at the surface, used during the crystallization of the buffer layer 21 of α-quartz. Subsequently, the sample will be cleaned with a mixture of sulfuric acid and hydrogen peroxide in a proportion of 4:1, respectively, to clean the ZnO residues resulting from the first cycle. Finally, a second cycle will be necessary for the crystallization and formation of ZnO microwires.

Measurements of the dimensions of the microwires were carried out by optical microscopy and field emission scanning electron microscopy.

A support composed of a layer of quartz (100) on silicon (100) covered with a layer (3) containing ZnO (110) microwires was obtained and then characterized.

The new epitaxy between the ZnO and the buffer layer 21 of α-quartz was determined by X-ray diffraction via a diffractometer sold under the trade name GADDS D8 in a Bruker assembly, 1,54056 Å copper irradiation.

The ZnO microwires thereby obtained have a density of 85% of the surface area, a thickness of 750 nm, a length of 12,000 nm and a width of 1,400 nm. The percolation of the microwires is perfect throughout the surface of the sample.

FIGS. 16a and 16b show the XRD diffraction diagrams (intensity in arbitrary units) as a function of the angle 2θ in degrees) and the degree of mosaicity of the ZnO microwire layer 3 obtained; the XRD analysis shows that ZnO is textured (110) with the crystallographic direction [110] of α-quartz parallel to the crystallographic direction [100] of the quartz (100) and of the silicon substrate (100). The ZnO microwires grew like in the previous case according to the relation [110] ZnO(110) // [100]*α-Quartz(100) // [100]*Si(100) and were positioned on the two domains of the quartz.

FIG. 17 gives the results of the topographic and microstructural study of the ZnO microwire layer 3 thereby obtained by the SEM of the vertical section of the layer. The continuity of the layer as well as the size of the crystals was characterized by SEB and AFM images. The layer obtained was formed of percolated homogeneous ZnO crystals, with a length of 12,000 nm, a width of 1,400 nm and a height of 750 nm. The continuity of the layer 3, as well as the size of the crystals, were characterized by MEB and AFM images. The layer obtained was formed of percolated homogeneous ZnO crystals, with a length of 12,000 nm, a width of 1,400 nm and a height of 750 nm.

### Example 4: Use for Energy Recovery Applications of the Second Example of Multilayer Material 1 According to the Invention Obtained in Example 3

FIG. 18 shows the use of the multilayer material according to the invention, as obtained in example 3 in a low frequency (61 Hz) energy recovery device. Such device can also recover energy and/or detect light by the photoelectric effect due to the axial p-n union between the ZnO crystals and the gold electrode.

### Example 5: Precise Control of the Resonance Frequency of α-Quartz Piezoelectric Membranes from the Control of the Size and Thickness Thereof

The resonance frequency and the displacement of the α-quartz piezoelectric membranes depend on the surface area and the thickness thereof. Control over such two morphological parameters makes it possible to precisely control the resonance frequency and to adapt the membrane morphology to the frequency range of the intended application.

A plurality of quartz-based piezoelectric membranes with different dimensions were produced, according to example 2. The membranes are squares with sides of 2 mm, 2.5 mm, 3 mm, 3.5 mm and 4 mm. Each of the membranes was produced in two series, one series with a thickness of 2 μm and one series with a thickness of 13 μm.

Such study proved the control over the size and the thickness of the membranes. The study highlights the impact of the parameters on the resonant frequency and the maximum amplitude of the devices. An increase in the surface area of the membranes decreases the value of the resonant frequency but increases the maximum displacement thereof. For a thickness of 2 μm, a 4 mm² membrane resonates at a frequency of 10.66 kHz with a displacement of 1.5 nm while a 16 mm² membrane resonates at 3.35 kHz with a displacement of 36.35 nm.

The results of the experimental data comprising the resonance frequency fᵣ and the maximum displacement for each membrane with a surface area of 4, 6.25, 9, 12.25, 16 mm² and a thickness of 2 and 13 μm are collated in Table 1 hereinafter. FIG. 19 also shows that a thinner membrane will resonate at a lower frequency than a thicker membrane. The two membranes have a surface area of 9 mm²: the membrane with a thickness of 2 μm resonates at fᵣ=8.16 kHz with a displacement Dₘₐₓ of 16.58 nm, whereas the membrane with a thickness of 13 μm resonates at fᵣ=26.55 kHz with a displacement Dₘₐₓ of 6.6 nm. In addition, a 13 μm thick membrane sweeps a wider frequency range than a 2 μm thick membrane.

TABLE 1

| | | 2 μm | 13 μm |
|---|---|---|---|
| 4 | mm² | fᵣ = 10.66 kHz | fᵣ = 54.25 kHz |
| | | Dₘₐₓ = 1.5 nm | |
| 6.25 | mm² | fᵣ = 9.88 kHz | fᵣ = 38.95 kHz |
| | | Dₘₐₓ = 15.31 nm | Dₘₐₓ = 3 nm |
| 9 | mm² | fᵣ = 8.16 kHz | fᵣ = 36.55 kHz |
| | | Dₘₐₓ = 16.58 nm | Dₘₐₓ = 6.6 nm |
| 12.25 | mm² | fᵣ = 5.68 kHz | fᵣ = 18 kHz |
| | | Dₘₐₓ = 20.98 nm | Dₘₐₓ = 7.5 nm |
| 16 | mm² | fᵣ = 3.35 kHz | fᵣ = 8.66 kHz |
| | | Dₘₐₓ = 36.35 nm | Dₘₐₓ = 11.8 nm |

### Example 6: Preparation of a Layer Based on Heteroepitaxially Grown ZnO Nanostructured Microwires on Silicon Substrate from a α-Quartz Buffer Layer According to the Method of the Invention, for Catalysis Applications

In the present example, it is shown that chemical etching of ZnO microwires with a dilute hydrochloric acid (HCl) solution makes it possible to nanostructure by generating a texture on the surface of epitaxially grown ZnO microwires. Indeed, after hydrothermal growth of the ZnO microwires, a chemical attack on the surface of the microwires with a HCl solution is used for controlling the surface of the ZnO (formation of a nanotexture). The planar conformation of the microwires and the method of nanostructuring by a posteriori chemical attack of the ZnO microwires leads to increasing the specific surface area of the material and then the catalytic activity. As an example, the yields of the catalyst are shown for the hydrogenation of CO₂ in order to form methanol after different degrees of attack in the ZnO microwire.

For this purpose, the first example of a multilayer material according to the invention obtained in example 1 is used.

Subsequently, a chemical attack was carried out by placing the sample of multilayer material in a solution of HCl with a concentration between 0.30-12 mM, stirred ultrasonically for 5 minutes. The following HCl concentrations were used: 0.37 0.75 1.48, 2.94 mM.

FIG. 20 shows low magnification SEM images of ZnO samples on quartz with different degrees of attack (20a), as well as an MET (20b) and an SEB (20c) image, with greater magnification, of the cross-section of a microwire along the crystallographic direction (001) after etching for 5 minutes under ultrasound with a 2.94 mM dilute HCl solution. In the figures, we can see the anisotropy of the attack in the crystallographic planes (001). The ZnO microwires thereby obtained have a density of 85% of the surface area, a thickness of 500 nm, a length of 12,000 nm and a width of 1000 nm. The graph in FIG. 20a shows that the STY increases significantly with the degree of chemical attack.

### LIST OF REFERENCES

1. Byeong-Yun Oh, Min-Chang Jeong, Tae-Hyoung Moon, Woong Lee, Jae-minutes Myoung, Jeoung-Yeon Hwang, and Dae-Shik Seo. Transparent conductive Al-doped zno films for liquid crystal displays. Journal of applied Physics, 99(12):124505, 2006.
2. Albert Polman, Mark Knight, Erik C. Garnett, Bruno Ehrler, and Wim C. Sinke. Photovoltaic materials: Present efficiencies and future challenges. Science, 352(6283), 2016.
3. H. Kim, C. M. Gilmore, J. S. Horwitz, A. Piqué, H. Murata, G. P. Kushto, R. Schlaf, Z. H. Kafafi, and D. B. Chrisey. Transparent conducting aluminum-doped zinc oxide thin films for organic light-emitting devices. Applied Physics Letters, 76(3):259-261, 2000.
4. Chin Boon, Law Yong, and Abdul Wahab. A review of ZnO nanoparticles as solar photocatalysts: Synthesis, mechanisms and applications. Renewable and Sustainable Energy Reviews, 81: 536-551, 2018.
5. Shuhua Liang, Xufeng Gou, Jie Cui, Yongguang Luo, Hongtao Qu, T E Zhang, Zhimao Yang, Qing Yang, and Shaodong Sun. Novel cone-like zno mesocrystals with co-exposed (10⁻ 11) and (000⁻ 1) facets and enhanced photocatalytic activity. Inorg. Chem. Forehead., 5:2257-2267, 2018.
6. Shaodong Sun, Xiaojing Yu, Qing Yang, Zhimao Yang, and Shuhua Liang. Mesocrystals for photocatalysis: A comprehensive review on synthesis engineering and functional modifications. Nanoscale Adv. 1:34-63, 2019.
7. Martin Drobek, Jae-Hun Kim, Mikhael Bechelany, Cyril Vallicari, Anne Julbe, and sang Sub Kim. MOF-based membrane encapsulated zno nanowires for enhanced gas sensor selectivity. ACS applied Materials & Interfaces, 8(13):8323-8328, 2016.
8. Wang, Z L; Song, J H. Piezoelectric nanogenerators based on zinc oxide nanowire arrays DOI: 10.1126/SCIENCE.1124005.
9. R. Raji and K. G. Gopchandran. ZnO nanostructures with tunable visible luminescence: Effects of kinetics of chemical reduction and annealing. Journal of Science: Advanced Materials and devices, 2:51-58, 2017.
10. Daniel Laudenschleger, Holger Ruland & Martin Muhler. Identifying the nature of the active sites in methanol synthesis over Cu/ZnO/Al2O3 catalysts. Nature Communications volume 11, Article number: 3898 (2020).
11. A. F. Soares, S. H. Tatumi, T. M. Mazzo, R. R. Rocca, and L. C. Courrol. Study of morphological and luminescent properties (TL and OSL) of ZnO nanocrystals synthetized by coprecipitation method. Journal of luminescence, 186: 135-143, 2017.
12. Jianhua Hu and Roy G. Gordon. Textured aluminum-doped zinc oxide thin films from atmospheric pressure chemical vapor deposition. Journal of applied Physics, 71(2):880-890, 1992.
13. Alessandro Fraleoni-morgera, Ilaria Cesini, and Pramod Kumar. hydrogrown ZnO nanorods as promising materials for low cost electronic skin. ChemNanoMat, 9: 1-18, 2019.
14. M. Z. Toea N. A. H. N. Jusoha S. Y. Punga K. A. Yaacoba A. Matsudab W. K. TanbS. S. Hanc. Effect of ZnO Seed Layer on the growth of ZnO Nanorods on Silicon Substrate. Materials today: Proceedings, Volume 17, Part 3, 2019, pages 553-559.
15. Yuhai Sun, Liminutes Chen, Yunfeng Bao, yujun Zhang, Jing Wang, Mingli Fu, Junliang Wu, and Daiqi Ye. The Applications of morphology controlled ZnO in catalysis. Catalysts, 6(188), 2016.
16. Tong Zhou, minutes Hu, Jia he, Ruicong Xie, Cuihua an, Chao Li, and Jun Luo. Enhanced catalytic performance of zinc oxide nanorods with crystal plane control. CrystEngComm, 21:5526-5532, 2019.
17. G. Sun, K. Zhao, Y. Wu, Y. Wang, N. Liu, L. Zhang, J. Phys. Condens. Matter 2012, 24, 295801.
18. X. H. WEI, Y. R. Li, J. Zhu, W. Huang, Y. Zhang, W. B. Luo, H. Ji, Appl. Phys. Lett., 2007, 90, 151918.
19. Wang et al., Chem 6, 419-430. https://doi.org/10.1016/j.chempr.2019.10.023.
20. J. Koike and H. leki, “Zinc oxide piezoelectric crystal film,” U.S. Pat. No. 5,432,397, 1995 Jul. 11.
21. T. Yamaguchi, N. Fujimura, S. Goto, and T. Ito, “formation of (11⁻ 20) ZnO Films by controlling the Selftexture and the relaxation of Film stress,” Mrs Proceedings, Vol. 263, pp. 297-302, 1992.
22. N. Emanetoglu, S. Liang, C. Gorla, Y. LU, S. Jen, and R. Subramanian, “epitaxial growth and characterization of high quality ZnO films for surface acoustic wave applications,” in IEEE Ultrasonics Symposium Proceedings. An International Symposium, Vol. 1, pp. 195-200, 1997.
23. J.-T. Luo, A.-J. Quan, Z.-H. Zheng, G.-X. Liang, F. Li, A.-h. Zhong, H.-L. MA, X.-H.. Zhang, and P. Fan, “Study on the growth of Al-doped ZnO thin films with (11⁻ 20) and (0002) Preferential orientations and their thermoelectric characteristics,” RSC advances, Vol. 8, no. 11, pp. 6063-6068, 2018.
24. Y.. Xiao, Y. Tian, S. Sun, C. Chen, and B. Wang, “growth modulation of simultaneous epitaxy of ZnO obliquely aligned nanowire arrays and film on r-plane sapphire substrate,” Nano Research, Vol. 11, no. 7, pp. 3864-3876, 2018.
25. Y.-T. Ho, W.-L. Wang, C.-Y. Peng, M.-H. Liang, J.-S. Tian, C.-W. LIN, and L. Chang, “growth of nonpolar (11⁻ 20) (001) ZnO Films on LaAlO3 ( ) substrates,” applied Physics Letters, Vol. 93, no. 12, p. 121911, 2008.

1. A multilayer material comprising:
a solid support coated at least partially with a buffer layer of textured α-quartz, the crystallographic direction of α-quartz being parallel to the crystallographic direction of silicon; and
on said buffer layer of α-quartz, a layer of one-dimensional micro-crystals of epitaxially grown ZnO, said micro-crystals being self-assembled.

2. The multilayer material according to claim 1, wherein the thickness of the one-dimensional micro-crystals of epitaxially grown ZnO is between 30 nm and 1.5 μm.

3. The multilayer material according to claim 1, wherein the length of the one-dimensional micro-crystals of epitaxially grown ZnO is between 5 nm and 30 μm.

4. The multilayer material according to claim 1, wherein said solid support is a material selected from silicon, solid quartz, mica, corundum, germanium dioxide, magnesium oxide, strontium titanate SrTiO₃, LaAlO₃, lithium niobate, lithium tantalate, cerium oxide, gadolinium and cerium mixed oxides of CE₍₁₋ₓ₎GdxO₂, wherein x is such that 0<x<1, lanthanum aluminate, gallium nitride, yttrium-doped zirconium dioxide or gallium orthophosphate.

5. The multilayer material according to claim 4, wherein said solid support is made of mono-oriented crystalline silicon.

6. The multilayer material according to claim 1, wherein said one-dimensional micro-crystals of epitaxially grown ZnO cover at least 40% of the surface area of said α-quartz buffer layer of said solid supports.

7. An electronic device comprising a multilayer material as defined in claim 5, wherein the electronic device is selected from a micro electro-mechanical system (MEMS), electro-mechanical materials, piezoelectric components, energy harvesters, photodetectors, mechanical wave specific filter oscillators, mechanical wave to electromagnetic wave transducers, acceleration and angular velocity sensors, mass sensors, or gas sensors.

8. A method for the manufacture of waveguides in the visible range, for the manufacture of supported catalysts, either in the presence or in the absence of noble metals or as an epitaxy template comprising using a multilayer material as defined in claim 1.

9. A method for the manufacture of transparent and conductive electrodes and the manufacture of electronic devices using said transparent and conductive electrodes comprising using a multilayer material as defined in claim 1.

10. A method of manufacturing a multilayer material as defined in claim 1, comprising the steps of:
A) preparing a buffer layer of textured α-quartz at least partially covering a solid support, so as to form a substrate for the epitaxial growth of ZnO micro-crystals;
B) preparing a first composition comprising a solvent, and at least one ZnO precursor;
C) preparing a second composition consisting of an aqueous solution of at least one heterocyclic organic compound having a diamond cage structure;
D) gradual feeding in, under stirring, of said second composition into said first composition, then maintenance under stirring for at least 10 minutes, in order to obtain a reaction mixture;
E) preparing the surface of said buffer layer using said second composition prepared during step C) or said reaction mixture prepared during step D) by feeding said substrate into a closed hydrothermal reactor, inside which the temperature is at least 60° C. and the pressure is at least 1 bar, for at least 15 minutes;
F) washing said buffer layer with an acid solution; then
G) heat treatment of the epitaxial growth of ZnO microcrystals by feeding said substrate and said reaction mixture on said substrate in the closed hydrothermal reactor inside which the temperature is at least 60° C. and the pressure is at least 1 bar, for at least 15 minutes; and
H) post-growth washing with, successively, demineralized water and then ethanol so as to dry the multilayer material thereby obtained.

11. The method according to claim 10, wherein during step B) zinc nitrate present in the proportion of 0.1 M in said first composition, is used as a ZnO precursor.

12. The method according to claim 10, wherein hexamethylenetetramine (HTMA) of formula (CH₂)₆N₄ is used during step C) as the heterocyclic organic compound contained in said second composition.

13. The method according to claim 10, wherein during step C), one or a plurality of additives selected from pH control agents, structuring or modifying agents or porosity promoting agents are added to said second composition.

14. The method according to claim 10, wherein said steps G) and H) are repeated one or more times on the same substrate.

15. A microelectromechanical system in the form of a piezoelectric resonant membrane comprising a multilayer material according to claim 1.

16. A method of nanostructuring a multilayer material according to claim 1, comprising controlled chemical etching ZnO microwires using an acid solution.

17. The multilayer material according to claim 2, wherein the thickness of the one-dimensional micro-crystals of epitaxially grown ZnO is 750 nm.

18. The multilayer material according to claim 3, wherein the length of the one-dimensional micro-crystals of epitaxially grown ZnO is 11 μm.

19. The method according to claim 11, wherein the zinc nitrate is Zn(NO₃)₂6H₂O.

20. The method according to claim 10, wherein during step C), one or a plurality of polymers, quaternary ammoniums and/or urea are added to said second composition.
